(19) United States
(12) Patent Application Publication
(10) Pub. No.: US 2010/0201230 A1
(43) Pub. Date: Aug. 12, 2010

(54) ELECTRIC POWER SYSTEM CONTROL SYSTEM WITH SELECTIVE ENCLOSURE

(76) Inventors: Edmund O. Schweitzer, III, Pullman, WA (US); Victor Hugo Barrangan Gonzalez, San Luis Potosi (MX); Richard A. Shulz, Tega Cay, SC (US)

Correspondence Address: Schweitzer Engineering Laboratories, Inc.;Richard Edge, 2350 NE HOPKINS COURT, PULLMAN, WA, 99163-5603, US

(21) Appl. No.: 12/697,614

(22) Filed: Feb. 1, 2010

Related U.S. Application Data
(60) Provisional application No. 61/149,296, filed on Feb. 2, 2009.
(60) Provisional application No. 61/149,298, filed on Feb. 2, 2009.

(51) Int. Cl. A47B 87/00; A47B 96/00; F16M 13/00; H05K 5/02

(52) U.S. Cl. 312/107; 312/294; 312/326; 312/237; 454/184

(57) ABSTRACT

An enclosure for electric power system control, monitoring, protection, and automation access devices, which includes a selective workspace enclosure. The enclosure includes a workspace enclosure for enclosing a workspace adjacent to a device for controlling, protecting, monitoring, and/or monitoring an electric power system, thereby providing a shelter or barrier to the elements for personnel accessing the device. Generally, the enclosure may be partitioned to include a number of cabinets, in each of which a number of devices may be installed. The enclosure may further include a platform, guide members, protective barriers and cover members (when retracted housed in a cover cabinet) to provide a shelter or barrier to the elements for personnel accessing the devices from a select workspace. The enclosure may be modular in that multiple modules, each of which may include its own protective cover member, may be installed adjacent to each other, such that enclosed workspaces may be selectively extended to provide enclosed workspaces only as needed.

### RELATED APPLICATION

The present patent application is a non-provisional patent application claiming the benefit under 35 U.S.C. §119(e) of U.S. Provisional Application Ser. No. 61/149,296, filed on Feb. 2, 2009 and entitled “MODULAR POWER SYSTEM CONTROL SYSTEM WITH SELECTIVE ENCLOSURE,” and U.S. Provisional Application Ser. No. 61/149,298, filed on Feb. 2, 2009 and entitled “SYSTEM FOR ENCLOSING AN OUTDOOR POWER SYSTEM CONTROL MODULE,” the complete disclosures thereof being incorporated by reference herein and a part hereof.

### TECHNICAL FIELD

This disclosure relates to electric power control and monitoring stations. More particularly, this disclosure relates to outdoor electric power control and monitoring stations and systems for enclosing such.

### BACKGROUND OF THE INVENTION

Effective electric power transmission and distribution requires equipment and devices for the control, monitoring, automation and protection of the electric power transmission or distribution systems. Examples of equipment that may be used on electric power transmission and/or distribution systems include switches, circuit breakers, capacitor banks, transformers, conductors, fuses, generators, current transformers (CTs), potential transformers (PTs), and the like. Devices may be in communication with such equipment for the monitoring, control, automation, and/or protection of the electric power system. Examples of these devices include the following: intelligent electronic devices (IEDs) such as protective relays, bay controllers, differential relays, distance relays, synchrophasor measurement units, synchrophasor measurement and control units, communications processors, synchrophasor vector processors, meters, programmable logic controllers, switches, generator relays, transformer relays, faulted circuit indicators, clocks, and the like. Devices may receive information from the equipment and act accordingly, based on the information received. Devices may also send control commands to the equipment. For example, a protective relay may be capable of receiving electric power system information (i.e. switch or breaker status from a switch or breaker, current from a CT, and/or voltage from a PT), process the gathered power system information, make a decision based on the information, and send a control command to the breaker to change status.

Power system substations are sites where several components of the electric power system converge in a single location, such as a yard. For example, a substation may be formed at the interface between an electric power transmission system and an electric power distribution system. The substation may include several step-down transformers where the relatively high-voltage from the transmission system is stepped down to the lower voltage of the distribution system. Substations may further be formed along various points of electric power transmission or distribution systems, such as where several lines of a particular system meet.

Substations often also include several devices for control, monitoring, automation and protection of an electric power transmission or distribution system. Such devices are typically mounted in panels and housed in a free-standing structure such as a building or modular enclosure. Substation buildings may include some means of physical security such as locked doors, intruder alarm systems, and the like such that the devices are not easily accessed by unauthorized persons.

Substation buildings are permanent, often bulky, require a significant amount of time to build, and use large amounts of energy to maintain adequate internal environmental conditions for personnel that may be working therein. Further, substation buildings are often placed in locations away from populated areas and may be difficult to access. Often, the need to access the devices occurs only periodically. As a result, some substation buildings are built and maintained only for a small amount of time that a person requires the benefits of the structure.

Alternatively, substation devices for control, monitoring, automation and protection of the electric power transmission or distribution system have been housed in enclosures, or otherwise known as modular power system control systems. FIG. 1 illustrates an example of a prior art enclosure 100. The prior art enclosure 100 is partitioned to include a number of cabinets 102, in each of which a number of devices 104 may be installed. Traditionally, an advantage of having an enclosure as compared to a substation building is in cost savings and portability. Nevertheless, the prior art modular enclosure 100 does not provide any shelter or barrier to the elements for personnel accessing the enclosure 100.

### SUMMARY OF THE INVENTION

The present invention is directed to a power system device enclosure, also known as a modular power system control system, including a selective workspace enclosure. Specifically, the present invention includes a workspace enclosure for enclosing a workspace adjacent to a power system device enclosure thereby providing a shelter or barrier to the elements for personnel accessing the power system device enclosure. Generally, the power system device enclosure may be partitioned to include a number of cabinets, in each of which a number of devices may be installed. The workspace enclosure may further include an optional platform, guide members, protective barriers and cover members (when retracted housed in a cover cabinet) to provide a shelter or barrier to the elements for personnel accessing the power system device enclosure from a select workspace. The power system device enclosure may be “modular” in that multiple modules, each including its own protective cover member, may be installed adjacent to one another, such that enclosed workspaces may be selectively extended to provide enclosed workspaces only as needed.

### BRIEF DESCRIPTION OF THE DRAWINGS

Non-limiting and non-exhaustive embodiments of the disclosure are described, including various embodiments of the disclosure with reference to the Figures, in which:

FIG. 1 is a perspective view of a prior art power system device enclosure;

FIG. 2A is a perspective view of a power system device enclosure having a workspace enclosure with guide members and one cover member in extended state to result in a workspace enclosure;

FIG. 2B is a perspective view of a power system device enclosure having a workspace enclosure with guide members and cover members in extended state to result in two workspace enclosures;

FIG. 2C is a perspective view of a power system device enclosure having a workspace enclosure with guide members and protective barriers in extended state;

FIG. 3A is a perspective rear view of a power system device enclosure having a workspace enclosure including an HVAC unit;

FIG. 3B is a perspective front view of a power system device enclosure having a workspace enclosure including a ventilation system for controlling the climate within a workspace;

FIG. 4A is a front view of a power system device enclosure including a workspace enclosure with guide members in retracted state;

FIG. 4B is a perspective view of a power system device enclosure including a workspace enclosure with guide members in retracted state;

FIG. 4C is a perspective view of a power system device enclosure including a workspace enclosure with guide members in partially extended state;

FIG. 5A is a side view of a guide member for a power system device enclosure of FIG. 4A in partially extended state;

FIG. 5B is a side view of a guide member for a power system device enclosure of FIG. 4A in fully extended state;

FIG. 6A is a perspective cross-sectional view of a cabinet for a power system device enclosure with the guide member and protective barrier in retracted state;

FIG. 6B is a perspective cross-sectional view of a cabinet for a power system device enclosure with the guide member in partially extended state and protective barrier in refracted state;

FIG. 6C is a perspective cross-sectional view of a cabinet for a power system device enclosure with the guide member and protective barrier in extended state;

FIG. 6D is a top cross-sectional view of a cabinet for a power system device enclosure with the protective barrier in retracted state;

FIG. 6E is a top cross-sectional view of a cabinet for a power system device enclosure with the protective barrier in extended state;

FIG. 6F is a side view of a power system device enclosure including a workspace enclosure with guide member and protective barrier in extended state;

FIG. 7A is a top cross-sectional view of a cover cabinet for a power system device enclosure;

FIG. 7B is a perspective view of a cover member system for a power system device enclosure;

FIG. 7C is another perspective view of a cover member system for a power system device enclosure;

FIG. 7D is a perspective view of a power system device enclosure showing the guide members in extended state.

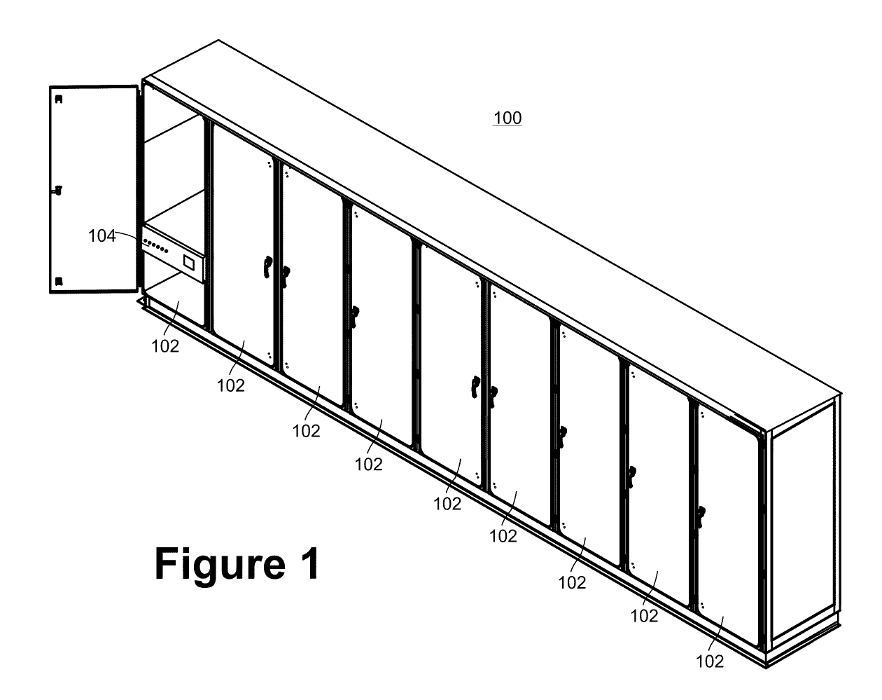

### DETAILED DESCRIPTION

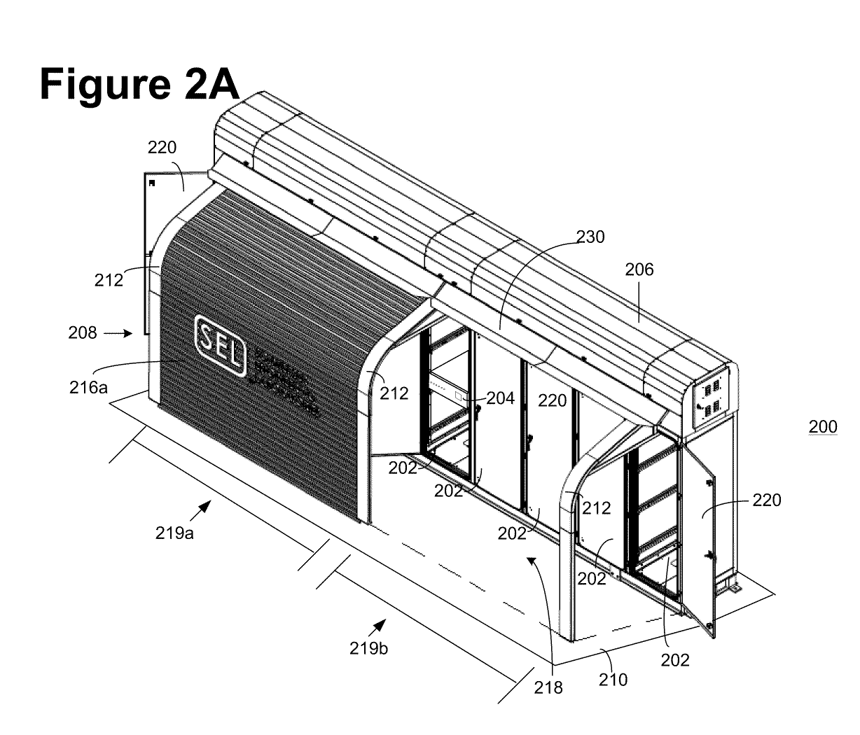

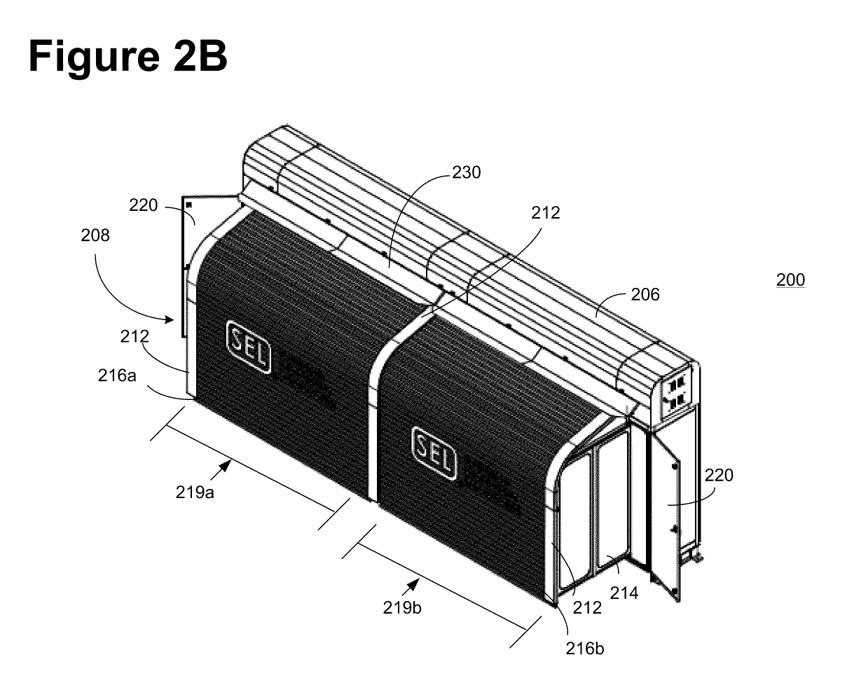

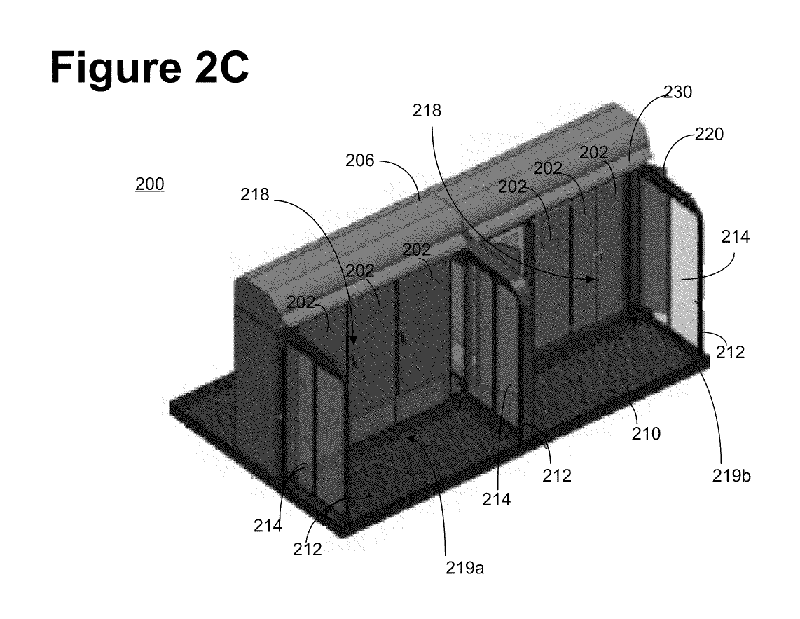

As illustrated in FIGS. 2A and 2B, the present invention is generally directed to a power system device enclosure 200 for housing devices including devices for control, monitoring, automation and protection of the electric power transmission or distribution system. The power system device enclosure 200 may further be used to house an alternative power supply for such devices such as, for example, a battery, a generator, a universal power supply, and the like. The power system device enclosure 200 maintains an advantage, as compared to a substation building, in cost savings and portability, while providing a configurable shelter or barrier to the elements for personnel accessing the power system device enclosure 200. Generally, the power system device enclosure 200 may be partitioned to include a number of cabinets 202, in each of which a number of devices 204 ( ) may be installed. In this embodiment, and throughout, the power system device enclosure is shown as having a plurality of cabinets; however, another embodiment of the power system device enclosure may include only a single cabinet. The present invention power system device enclosure further includes a workspace enclosure 208 including an optional platform 210, guide members 212, protective barriers 214 and cover members 216a, 216b (when refracted housed in a cover cabinet 206) to provide a shelter or barrier to the elements for personnel accessing the power system device enclosure 200 from a select workspace 218 adjacent to the power system device enclosure 200.

The embodiments of the disclosure will be best understood by reference to the drawings, wherein like parts are designated by like numerals throughout. It will be readily understood that the components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure.

In some cases, well-known features, structures or operations are not shown or described in detail. Furthermore, the described features, structures, or operations may be combined in any suitable manner in one or more embodiments. It will also be readily understood to those skilled in the art that the components of the embodiments as generally described and illustrated in the figures herein could be arranged and designed in a wide variety of different configurations.

Referring to FIGS. 2A-2C, housed within the power system device enclosure 200 are power system devices 204 that are typically used in electric power system protection, control, automation, and monitoring. The power system devices 204 may be housed, selectively grouped and/or arranged within each cabinet 202 and accessed by cabinet doors 220. The cabinet doors 220 may include a handle, locking mechanism, biometric security mechanism or other security mechanism for providing secured access to the power system devices 204. The cabinet doors 220 may further engage a switch which turns on or off lighting within the cabinet 202. For example, upon opening the cabinet door 220, a switch may be engaged to automatically turn on a light within the cabinet 202. Upon closing the cabinet door 220, the switch may be disengaged thereby automatically turning off the light within the cabinet 202.

The exterior of the present invention power system device enclosure 200 and cabinet doors 220 may be generally constructed of environmentally-hardened panels. The environmentally-hardened panels provide protection from the possibly harsh environments where substations may be located (e.g., from sun, heat, snow, rain, etc.). Both the power system device enclosure 200 and power system devices 204 housed therein may include further environmental protections such as conformal coating components thereof to protect against harsh environments and airborne contaminants, such as hydrogen sulfide, chlorine, salt, and moisture.

Typical power system devices 204 are designed to operate within a wide environmental operating range. For example, power system devices available from Schweitzer Engineering Laboratories, Inc. of Pullman, Wash. are typically rated to function at temperatures from ranging from about −40° C. to about +85° C. (−40° F. to +185° F.). Such temperatures are rarely experienced outside of structures. However, confinement of the power system devices 204 within an enclosure may cause the temperatures to exceed this temperature range. For example, the heat emitted by power system devices may cause the temperature within an enclosure to rise above the outdoor temperature.

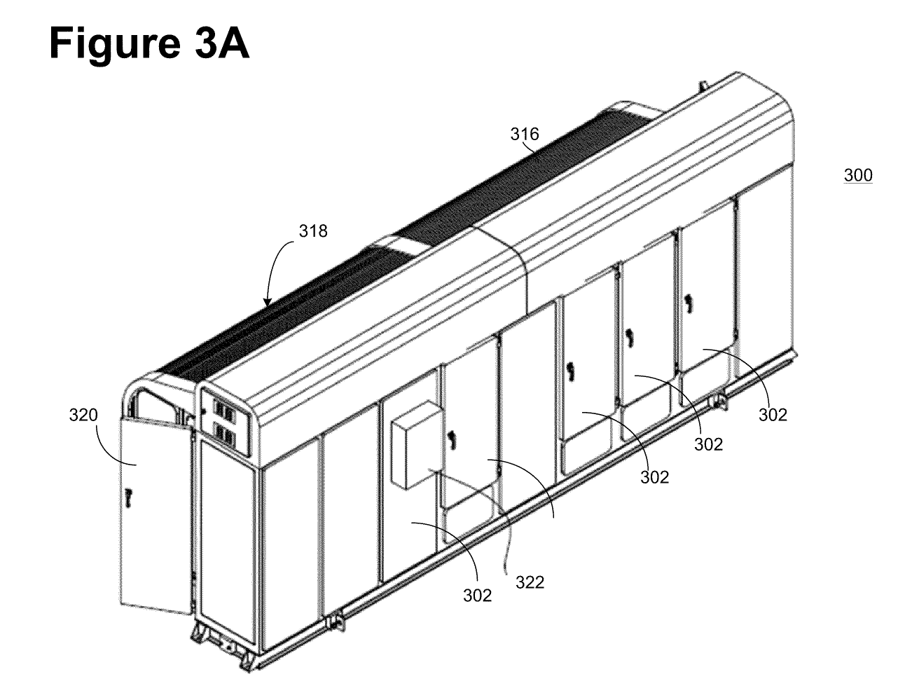

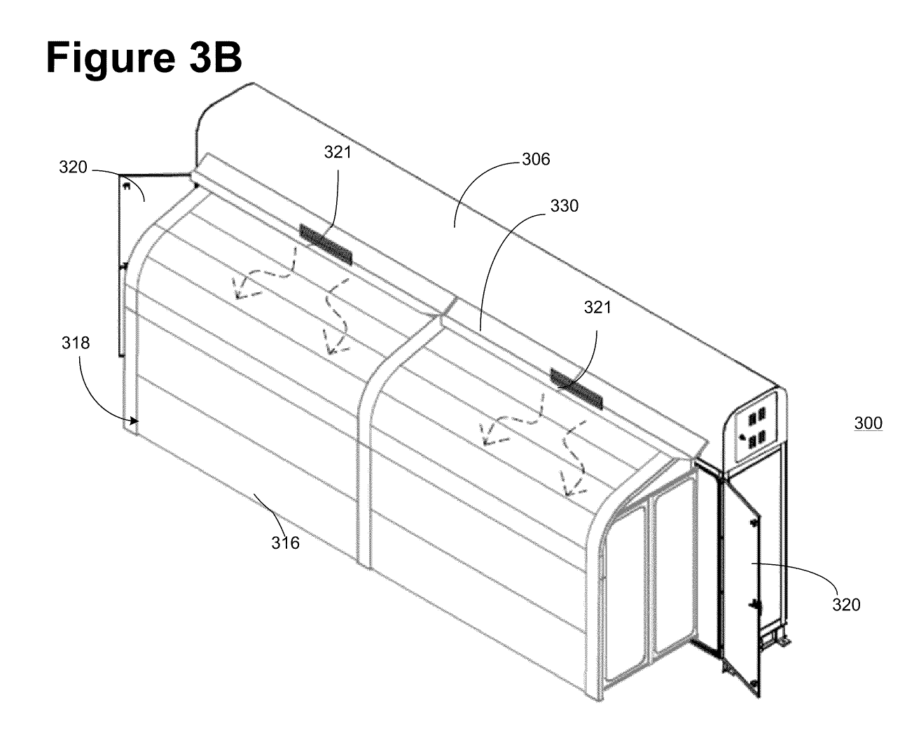

In accordance with an embodiment of the present invention as shown in FIGS. 3A and 3B, one of the cabinets 302 may include a heating, ventilating, air conditioning or other HVAC unit 322. In this embodiment, the HVAC unit 322 may be used to regulate and control the temperature of any of the other cabinets 302 through a ventilation system 321 such as ducting or any other conduit between the cabinets 302.

As shown specifically in FIG. 3B, a ventilation system 321 from the HVAC unit 322 extending to the front of the power system device enclosure 300 may further be included to provide heating, ventilation, and/or air conditioning to personnel accessing the side of the power system device enclosure 300 from the workspace 318. The output of the ventilation system 321 for the workspace may be positioned below the cover cabinet lip 330 beneath the cover cabinet 306. As such, when the cover member 316 is extended so that it encloses the workspace 318, the ventilation system 321 may be used to regulate the temperature in the enclosure.

Moreover, the ventilation system 321 for the workspace 318 may or may not be separately controllable from the ventilation system 321 for regulating and controlling the temperature within the cabinets 302 of the power system device enclosure 300. In another example, the ventilation system 321 for the workspace 318 may also be coupled to a cabinet 302 light switch. In this arrangement, upon opening the cabinet door 320, a switch may be engaged to automatically turn on the ventilation system 321 and a light within the cabinet 302. Upon closing the cabinet door 320, the switch may be disengaged thereby automatically turning off the ventilation system 321 and light within the cabinet 302. In another embodiment, the switch for the ventilation system 321 may be separate and apart from the switch of the lighting within the cabinet 302.

Referring back to FIGS. 2A-2C, to protect personnel accessing the power system device enclosure 200 from the environmental conditions, the power system device enclosure 200 may include an adaptable workspace enclosure 208 for at least part of the workspace 218. The adaptable workspace enclosure 208 may include an optional platform 210, guide members 212, protective barriers 214, and cover members 216a, 216b.

In many cases, an enclosed workspace is only necessary for a portion of the control system. The power system device enclosure 200 includes a number of cabinets 202, in each of which a number of power system devices 204 may be installed. Often, only a single power system device 204 or a small group of power system devices 204 need to be accessed. Devices may need to be accessed to, for example, retrieve data, install data (firmware upgrades, etc. . . . ), change settings, review settings, and the like. Accordingly, in conditions that may require an enclosed workspace 218 for accessing only a select number of power system devices 204, it may be advantageous to selectively extend an enclosure 208 around only the cabinets 202 housing the power system devices 204 that need to be accessed. For example, in FIG. 2A only cover member 216a is extended, as compared to FIG. 2B where both cover members 216a, 216b are extended.

Further, in many cases, the workspace enclosure 208 only needs to be extended during relatively short periods of time when the power system devices 204 need to be accessed by personnel. Again, it may be advantageous to selectively extend a workspace enclosure 208 for only the times at which the power system devices 204 housed in a particular cabinet 202 need to be accessed. Thus, the present invention provides a system for selectively enclosing a workspace 218. The workspace enclosure 208 may be selectively extended as needed and where needed.

Apparent are several advantages to such a workspace enclosure 208. One advantage is that where only a relatively small number of power system devices 204 are needed, a small workspace enclosure 208 may be provided with the cabinets 202 needed to house the power system devices 204, and enclosure sufficient for selectively enclosing the power system devices 204. Where additional power system devices 204 are later needed, a second power system device enclosure 200 and workspace enclosure 208 may be provided. A second such installation may be installed adjacent to the first installation, each selectively and separately enclosable.

As illustrated in FIGS. 2A and 2C, the power system device enclosure 200 may be optionally mounted on a platform 210. The platform 210 may extend beyond the footprint of the power system device enclosure 200 and at least in part define the workspace 218 and/or the footprint of the workspace enclosure 208. The platform 210 may be constructed of any material known in the art of modular enclosures or substation buildings. The platform 210 may be installed over or be in the form of a concrete pad or the like. In another example, the platform 210 may be a separate piece of material from the power system device enclosure 200, and the power system device enclosure 200 may be installed onto the platform 210.

As illustrated in FIGS. 2A-2C, the workspace enclosure 218 may include one or more guide members 212 to form sides of the workspace enclosure 218 that extend in a direction substantially perpendicular from the power system device enclosure 200. More specifically, the guide members 212 may include a track for guiding protective barriers 214 to form the sides of the workspace enclosure 218. The protective barriers 214 may include windows or a panel of transparent material such as a glass, a polymer, or the like. The frame of the protective barriers 214 may be formed from an opaque material such as metal, wood, or the like. The protective barriers 214 may be in the form doors, as shown, such that the workspace is accessible without removing the cover members 216a, 216b. The protective barriers 214 may include a locking or other security mechanism for providing controlled access to the power system device enclosure 200.

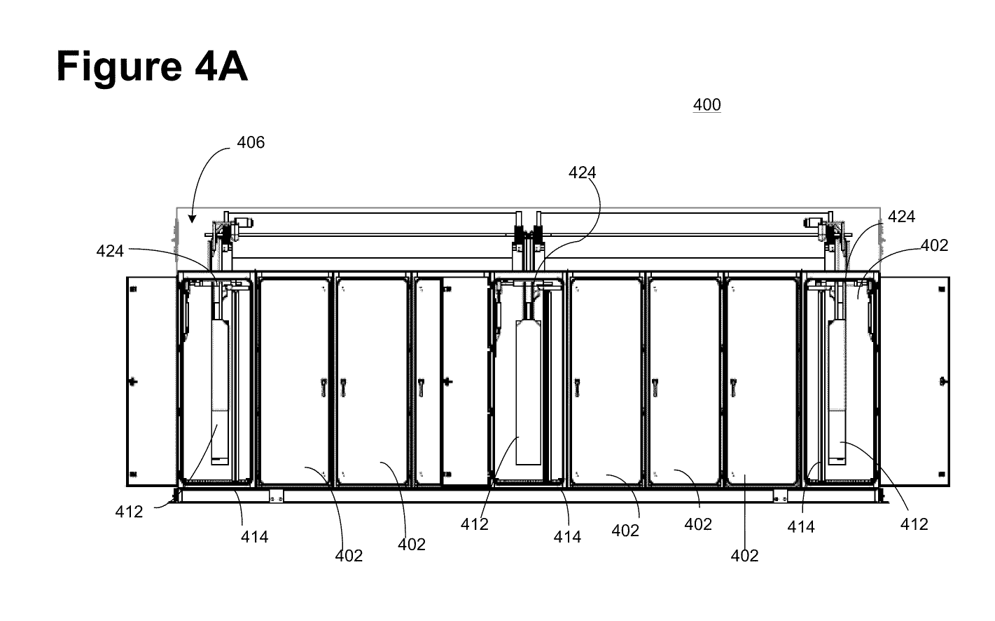

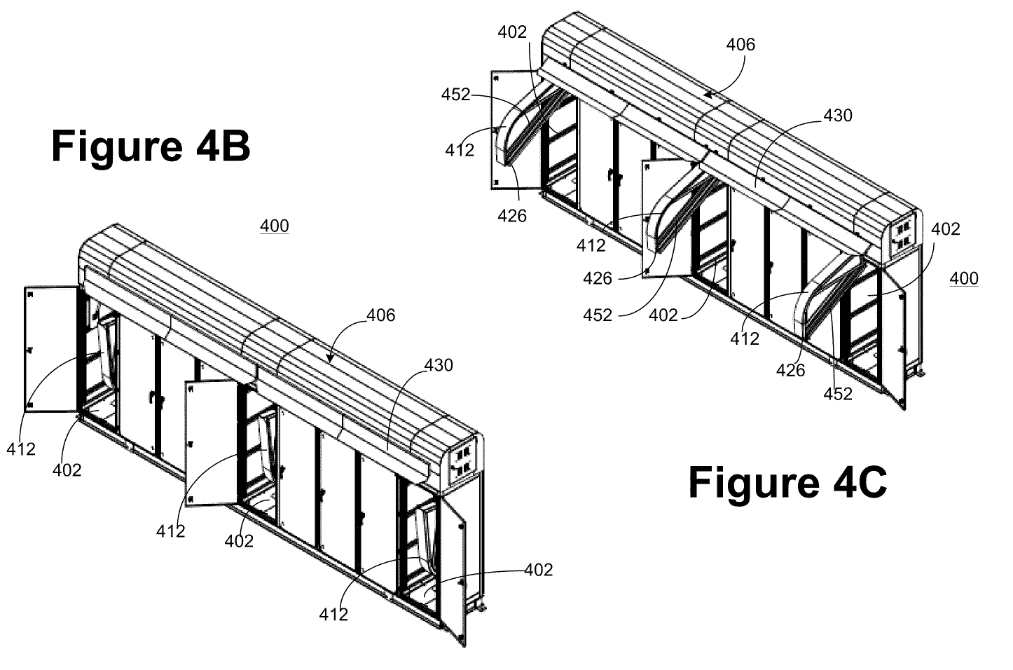

As shown in FIGS. 4A-4C, the guide members 412 and protective barriers 414 may be housed within one of the cabinets 402. When an enclosed workspace is desired, the guide members 412 are extended by opening the guide cabinet 402 and extending the guide members 412 in a direction substantially perpendicular to and away from the modular enclosure 400. The guide member 412 generally includes an upper hinge 424 and a lower hinge 426 such that it may be retracted and foldably stored within one of the cabinets 402.

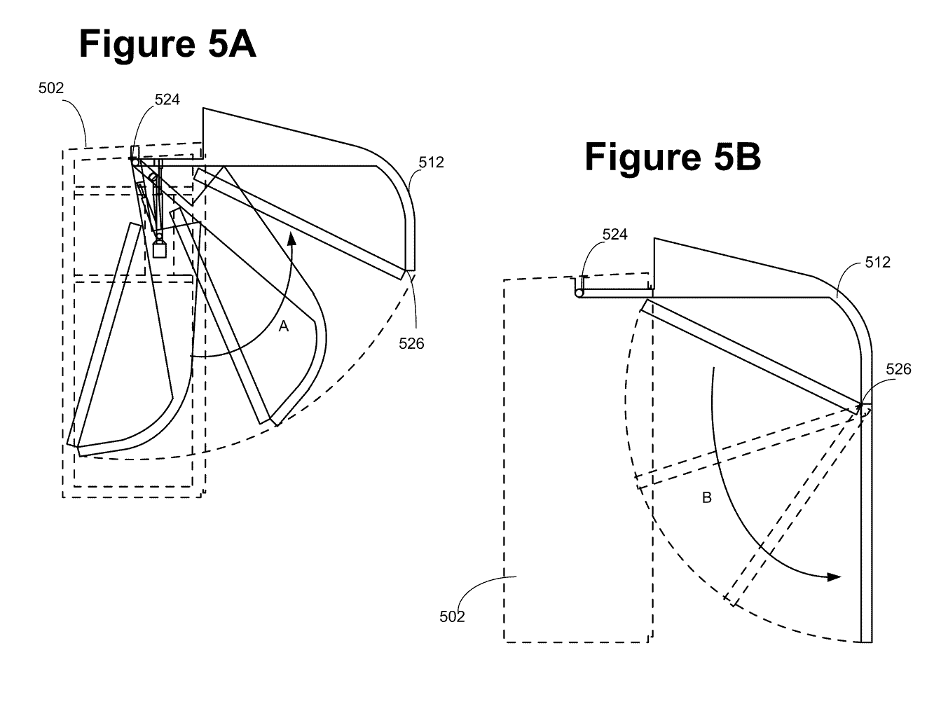

As shown in FIGS. 5A and 5B, the upper hinge 524 may be in the form of a hydraulic hinge to assist a user in extending and foldably storing each of the guide member 512. As specifically illustrated in FIG. 5A, in order to extend the guide member, first the upper half is lifted out of the cabinet 502 in a generally upwards direction (shown at arrow A), by employing an upper hinge 524. Once the upper half of the guide member 512 is extended, the lower half may be unfolded, by use of a lower hinge 526. As shown in FIG. 5B, the lower half of the guide member is folded outwards, away from the cabinet 502 (shown at arrow B) until the guide member 512 is fully extended.

Additionally, situated near the lower hinge 526 may be a handle (not shown) for assisting the user in extending and foldably storing the guide member 512 in the cabinet 502. Near the lower end of the guide member 512 is a link or other securing means (not shown) for securing the lower end to the upper end of the guide member 512. This link, or other securing means, prevents movement of the lower end of the guide member 512 relative to the upper end of the guide member 512 during storage thereof.

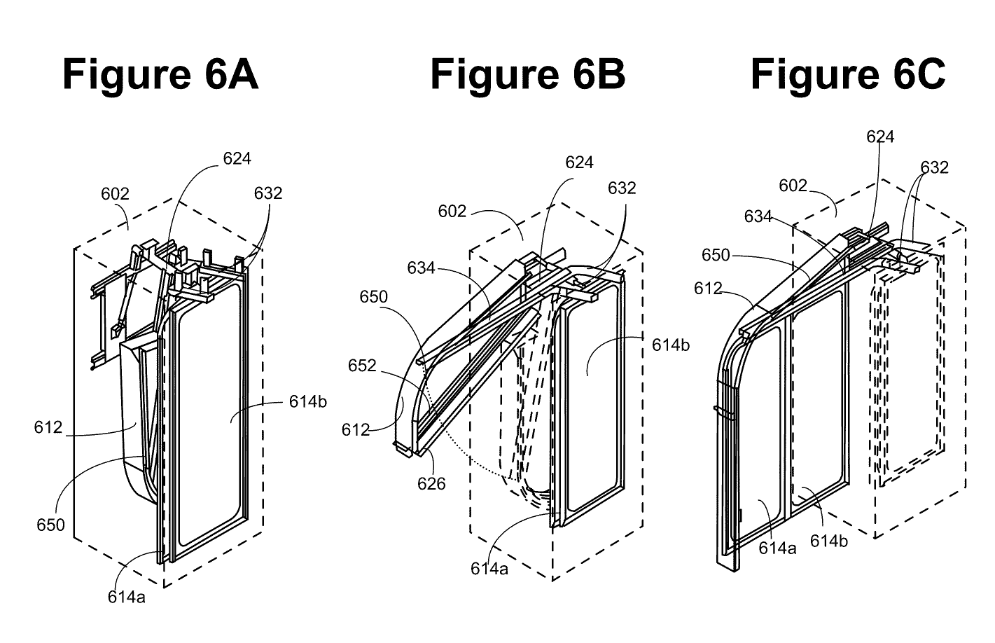

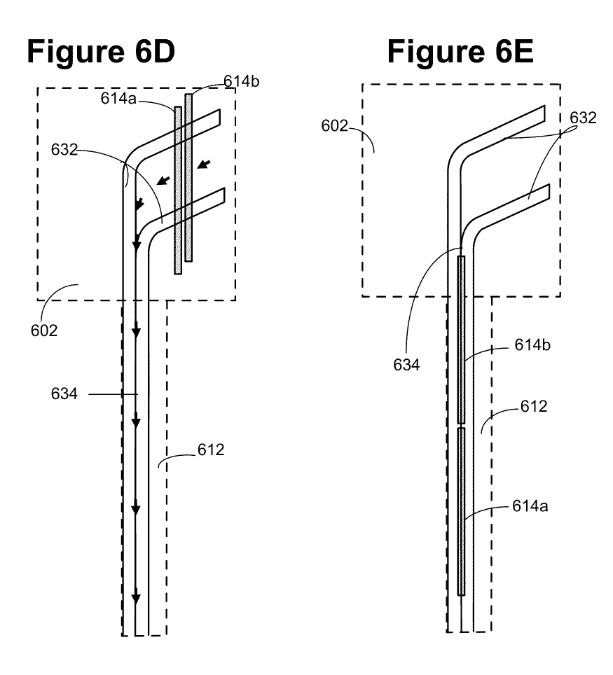

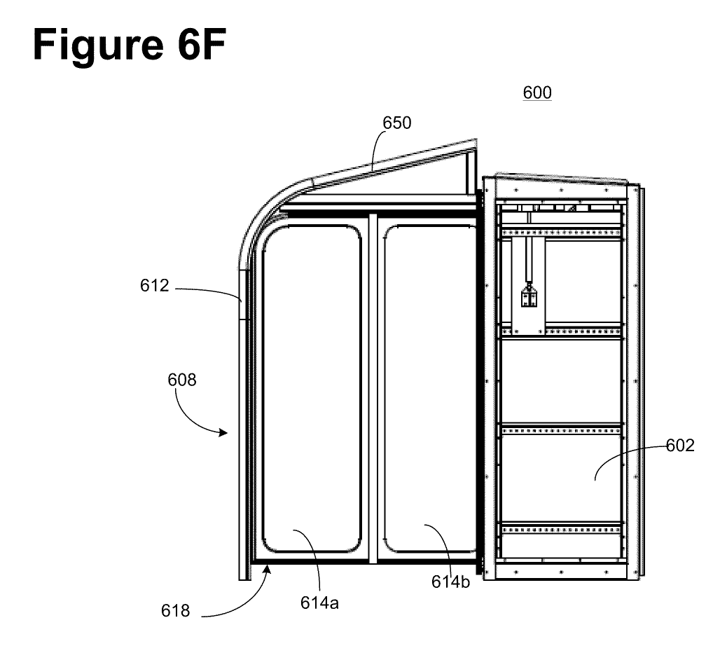

FIGS. 6A-6C illustrate how the guide member and protective barriers of power system device enclosure 600 may be extended from a retracted position. As shown in FIG. 6A, the protective barriers 614a, 614b and guide member 612 may be stored within the cabinet 602. In order to extend the protective barriers 614a, 614b, first the guide member 612 must be extended. FIG. 6B illustrates the guide member 612 in a partially extended position, by employing the upper hinge 624, while the protective barriers 614a, 614b remain retracted. After the first half of the guide member 612 is extended, the second half may be unfolded, by use of a lower hinge 626, and the guide member 612 may be fully extended, as shown in FIG. 6C. Once the guide member 612 is fully extended, the protective barriers 614a, 614b may be extended along a track defined in the guide member 612.

As shown in FIGS. 6A-6E, each guide member 612 includes a track for guiding the protective barriers 614a, 614b, such that they may be extended or retracted smoothly. As illustrated in FIGS. 6B and 6D, when the protective barriers 614a, 614b are retracted, they are situated within the cabinet 602 on a dual track 632 side-by-side, parallel to the guide member 612. As the dual track 632 begins to extend out of the cabinet 602, it combines to form a single track 634. In order to extend the protective barriers 614a, 614b, the protective barriers 614a, 614b are slidably guided from a dual track 632 in the cabinet 602 onto a single track 634 outside of the cabinet 602. Each protective barrier 614a, 614b includes two or more pivotal guide rollers, which may be in the form of balls, pivotal wheels, or other pivotal rollers. These pivotal guide rollers are situated between the track and the top of the protective barriers such that the pivotal guide rollers engage the track. The pivotal guide rollers allow the protective barriers to navigate from the dual track to the single track so that they may be guided from a retracted (or opened) position to an extended (or closed) position.

As depicted in FIGS. 6C and 6E, once the protective barriers 614a, 614b are on the single track 634 they are no longer side-by-side, but rather are in single-file along the length of the track 634, such that the first protective barrier 614a is situated next to the second protective barrier 614b. The single track 634 extends the length of the guide member 612 and is positioned directly beneath it. Therefore, when extended along the single track 634, the protective barriers 614a, 614b are situated in line with the guide member, directly beneath it, rather than being in parallel to the guide member 612.

Moreover, each guide member 612 may include another track 652 extending from the single track 632 and spanning the entire length of the guide member 612 on its interior side. When the protective barriers are extended, this track 652 permits the entire length of the guide member 612 and the front side of the protective barrier 614a to be flush. As shown in FIG. 6F, when extended, the protective barriers 614a, 614b form the sides of the workspace enclosure 608, securely shielding the workspace 618 from the environment.

As shown in FIGS. 6A-6F, the each guide member 612 further includes a cover track 650 or guide for positioning the cover member over the workspace 618. Specifically, this cover track 650 may extend the length of the guide member 612 on its lateral sides such that when the guide members 612 are extended, the cover member 616 may be smoothly extended from its rolled and retracted position to its extended position.

The guide members 612 may be of a size sufficient to allow a person to stand and work within the enclosed workspace, yet small enough to be completely retracted to within the cabinet 602. The guide members may be from about 1 foot to about 10 feet deep and from about 5 feet to about 10 feet tall. The guide members may be around 3 feet deep to about 7 feet tall.

FIG. 2B illustrates a workspace enclosure 208 with extended guide members 212, protective barriers 214, and a cover member 216 extended to create an enclosed workspace 218. The cover member 216 may be formed using a cover that is flexible in at least one direction and that, when extended, follows the horizontal portion of the guide to the vertical portion of the guide member 212, and contacts a platform 210. When retracted, the cover member 216 may be rolled within a cover cabinet 206 mounted on the top portion of the modular enclosure 200. As illustrated in FIGS. 2A-2C, the cover cabinet 206 may include a cover cabinet lip 230, which extends between the cover cabinet 206 and cover member 216 so as to protect the inside of the cover cabinet 206 from the elements. Specifically, the cover cabinet lip 230 prevents debris and small animals from entering the cover cabinet 206, which could interfere with retracting or extending the cover member 216.

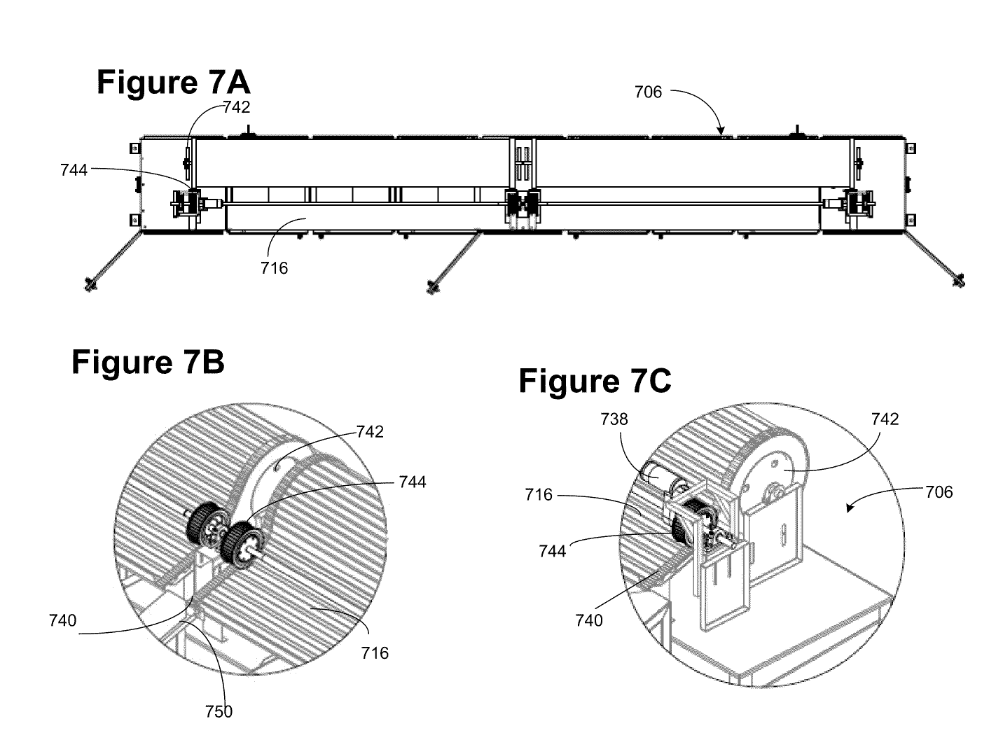

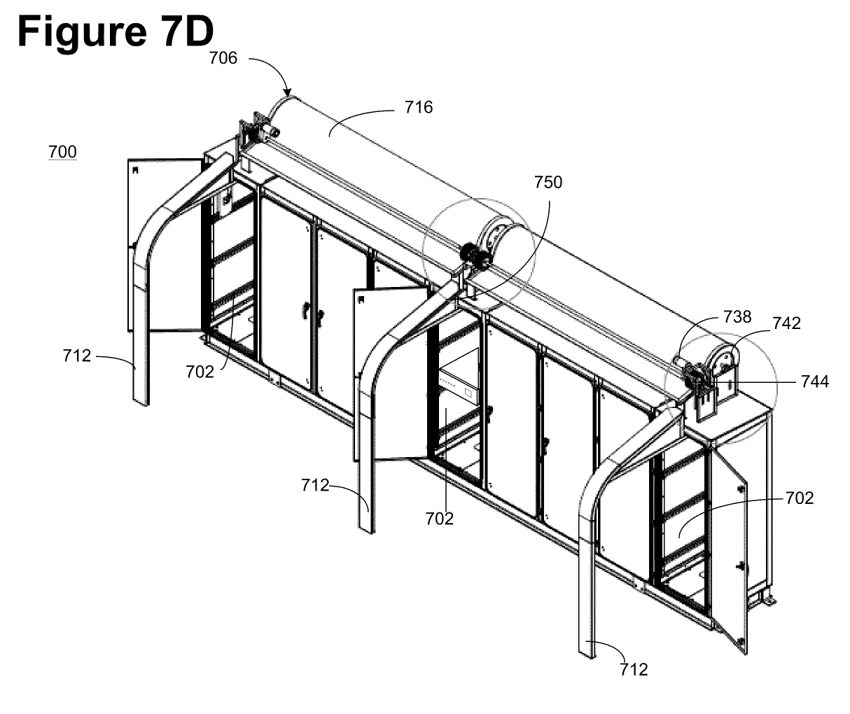

As shown in FIGS. 7B and 7D, the cover cabinet 706 of the power system device enclosure 700 may have a cover track 750 in which the cover member 716 runs, which extends the length of the guide member 712 on its lateral sides. As mentioned above, the cover track 750 may cooperate with the guide members 712, when the guide members 712 are extended, such that the cover member 716 smoothly extends from its rolled and retracted position to its extended position. Specifically, the cover member 716 may be unrolled through the cover track 750 in the cover cabinet 706 and directly through the cover track 750 along the sides of the guide members 712 to enclose the workspace. The cover member 716 may be extended to fully or, otherwise, partially cover the workspace.

As shown in FIGS. 7A-7D, the cover cabinet 706 may include a cover motor 738 that, when operated, retracts or extends the cover member 716. The cover member 716 includes a vertical section of cover treading 740, which defines a plurality of grooves, and is positioned on each lateral edge of the cover member 716, extending the length of the cover member 716. In order to retract the cover member, the motor 738 operates a pulley 744, which grips the corresponding grooves defined in the section of cover treading 740 and pulls the cover member 716 upwards, rolling the cover member 716 around a spindle 742 until the cover member 716 is enclosed by the cover cabinet 706. By contrast, to extend the cover member 716, the motor operates the pulley 744 such that it pulls the cover member in the opposite direction, unrolling the cover member 716 through the cover track 750 and along the guide member 712. The motor 738 for the cover member 716 may be activated by a switch located in one of the cabinets 702.

As shown in FIG. 7D, the substantially horizontal portion of the guide members 712 slopes slightly downwardly from the cover cabinet 706 such that when the motor 738 operates to unroll the cover member 716, gravity pulls the leading edge of the cover member 716 slightly down and along the horizontal portion of the guide members 712.

In another embodiment (not shown), as an alternative to the motor, the cover member may be extended and/or retracted using a manual means such as a chain or a rope in rotating communication with the spindle on which the cover member may be rolled. In this arrangement, the pulley is engaged manually such that by pulling on one side of the chain or rope the pulley operates in one direction, gripping the groves defined in the section of cover treading, and pulling the cover member such that it is unrolled and extended. By pulling on the other side of the chain or rope the cover member is rolled and retracted. Further, the cover member may be extended by pulling on the leading edge of the cover member along the guide members and to the platform. The cover member may then be retracted using the chain or rope to activate the pulley. In one embodiment, the cover member is provided with a motor for extension/retraction, and a manual means for extension/retraction in case the motor malfunctions or power to the motor is unavailable.

In yet another embodiment, the cover member is formed from a material that is substantially stiff in compression such that when the motor is operated to extend the cover, the leading edge of the cover is pushed along the horizontal portion of the guide members. In this embodiment, the cover member is sufficiently flexible in at least one direction such that it may flex as it passes from the horizontal portion of the guide members to the vertical portion of the guide members. Also, the cover member may be sufficiently flexible in at least one direction such that it may be rolled on the spindle when in the retracted position.

The purpose of the cover member may be to increase the protection of the personnel accessing the devices and to increase the protection of the devices from possible environmental conditions upon opening of the cabinets housing the devices. Some examples of such environmental conditions includes rain, sleet, snow, blowing dust or debris, airborne corrosive chemicals, and the like. To achieve this objective, the cover member may be formed of a material that is substantially impervious to these conditions. The cover member may further be required to withstand some degree of physical deformation from, for example, wind, the weight of collected snow (on the horizontal portion, for example), the weight of collected water (on the horizontal portion, for example), and the like. To that end, the material chosen for the composition of the cover member may be required to withstand a degree of physical deformation. To accomplish this, the cover member may be formed from materials such as metal, plastic, composite materials, or the like.

In one embodiment, the cover member is comprised of a rolling door. Rolling doors are available from numerous manufacturers and may be formed from one of various materials. For example, rolling doors may be purchased from Wayne Dalton Corporation of Mt. Hope, Ohio. Rolling doors are especially well-suited for this application because they are flexible in one-direction only, and are substantially flexible in that direction to allow for rolling on a spindle as well as the transition from the horizontal portion to the vertical portion. Further, rolling doors are sufficiently resistant to physical deformation as well as many environmental conditions such as rain, snow, blowing debris, airborne corrosives, and the like. Rolling doors further provide additional security due to their strength. Further still, windows can be placed within rolling doors such that when the cover member is extended, an occupant of the workspace enclosure may be capable of viewing outside. Windows may also be advantageous in that they allow ambient light to enter the workspace enclosure.

Rolling doors may also be provided using any one of a number of possible materials. Some examples of the possible materials for the rolling door cover member include: galvanized steel, stainless steel, aluminum, wood, polymers, and the like. Further, rolling doors may be provided with insulation therein, thus providing additional protection from the possible environmental conditions. The choice of material for the cover member may be made to minimize weight, minimize price, maximize anti-corrosive properties, maximize water impenetrability, maximize security, and the like.

In one embodiment, the workspace enclosure functions to enhance security of the modular enclosure housing the protective devices. In this embodiment, the cover member includes a locking mechanism to secure the cover member in extended position unless unlocked. Also, where one or more guide members are fitted with protective barriers in the form of access doors (or include access doors), these access doors may include a locking mechanism such that access to the panels through the protective barrier may be accomplished only by unlocking the door. Further, the guide members may include locking mechanisms that hold the position of the guide members in an extended position unless unlocked. The locking mechanisms may be disengaged without the use of a key, but may be accessible only from within the enclosed workspace. That is, in order to disengage the locking mechanisms of the guide members themselves, one must first enter the enclosed workspace by either: 1) unlocking, opening, and passing through the cover member; or, 2) unlocking, opening, and passing through a lockable door included within, or formed from the protective barrier.

The power system device enclosure and workspace enclosure are modular in that each module may stand on its own as needed to both provide protection, monitoring, control, and/or automation to the electric power system as well as providing a selectively extendable workspace enclosure. A single module may be installed in an electric power system substation to provide the needed power system protection, monitoring, control, and/or automation. As additional protection, monitoring, control, and/or automation is needed, additional modules may be added by installing additional modules. The additional modules may be installed adjacent to the existing module.

Each module has selectively and separately extendable covers to selectively create enclosed workspaces. The Figures illustrate a first module and a second module installed adjacent to each other. For example, FIG. 2A illustrates a first module 219a and second module 219b where the protective cover for the second module is retracted such that the second workspace enclosure is removed. The first module 219a, however, has its protective cover 216a extended to create a first workspace enclosure 208 in which personnel may access power system devices 204 mounted within the first module 219a. Several modules may be installed accordingly to create rows and/or banks of modular power system control systems with selective enclosures. FIG. 2B illustrates the same first module 219a and second module 219b with both protective covers 216a, 216b extended to create a first and second workspace enclosure in which personnel may access devices housed therein.

While specific embodiments and applications of the disclosure have been illustrated and described, it is to be understood that the disclosure is not limited to the precise configuration and components disclosed herein. Various modifications, changes, and variations apparent to those of skill in the art may be made in the arrangement, operation, and details of the methods and systems of the disclosure without departing from the spirit and scope of the disclosure.

1. A workspace enclosure for enclosing a workspace adjacent to a cabinet for housing a power system device; the workspace including
a cover member which may be selectively extended from the cabinet to provide an enclosure for the workspace.

2. The workspace enclosure of claim 1 further including a guide member coupled to the cabinet, the guide member including a track for guiding the selective extension of the cover member.

3. The workspace enclosure of claim 1 further including a platform, upon which the cabinet is mounted.

4. The workspace enclosure of claim 2 wherein the guide member may be foldably stored within the cabinet.

5. The workspace enclosure of claim 4 wherein the guide member extends from the cabinet in a direction generally away from and perpendicular to the cabinet.

6. The workspace enclosure of claim 4 wherein the guide member includes an upper hinge and a lower hinge to allow the guide member to be folded and retracted into the cabinet.

7. The workspace enclosure of claim 6 wherein the upper hinge is a hydraulic hinge to assist in the selective extending of the guide member in the cabinet.

8. The workspace enclosure of claim 4 further including a link for securing one end of the guide member to another end of the guide member, thereby preventing movement of the ends relative to each other during storage thereof.

9. The workspace enclosure of claim 4 further including at least one protective barrier engaging the guide member to form a side of the workspace enclosure.

10. The workspace enclosure of claim 9, wherein the guide member further includes a track for guiding the protective barrier to form the side of the workspace enclosure.

11. The workspace enclosure of claim 10, further including multiple tracks situated within the cabinet engaging a plurality of protective barriers such that the plurality protective barriers may be stored in the cabinet.

12. The workspace enclosure of claim 11, further including a track extending out from the cabinet and engaging the plurality of tracks within the cabinet for extension of each of the protective barriers out from the cabinet.

13. The workspace enclosure of claim 11 wherein the guide member further includes an interior track spanning the entire length of the guide member up to the single track for further securing the protective barriers to the guide member.

14. The workspace enclosure of claim 9 wherein the protective barrier comprises a door.

15. The workspace enclosure of claim 9 wherein the protective barrier includes a security mechanism for providing controlled access to the workspace enclosure.

16. The workspace enclosure of claim 9 wherein the protective barrier is housed within the cabinet.

17. The workspace enclosure of claim 1 wherein the cabinet includes an HVAC unit.

18. The workspace enclosure of claim 17 further including a first ventilation system for regulating and controlling the temperature of the cabinet.

19. The workspace enclosure of claim 18 wherein the HVAC unit further regulates and controls the temperature of the workspace enclosure.

20. The workspace enclosure of claim 19 wherein the first ventilation system is separately controllable from a second ventilation system for regulating and controlling the temperature of the workspace enclosure.

21. The workspace enclosure of claim 1, wherein the cover member includes a securing mechanism to maintain the cover member in an extended position.

22. The workspace enclosure of claim 1 further including a cover cabinet for housing the cover member.

23. The workspace enclosure of claim 1 further including a pulley mechanism for selectively extending the cover member.

24. The workspace enclosure of claim 23 further including a motor for operating the pulley.

25. The workspace enclosure of claim 1, further comprising a plurality of cabinets.

26. The workspace enclosure of claim 25, wherein the cover member may be selectively extended from the plurality of cabinets to provide the enclosure for the workspace.

27. The workspace enclosure of claim 25, further comprising an HVAC unit for regulating and controlling the temperature of the plurality of cabinets through a ventilation system between each of the plurality of cabinets.

28. The workspace enclosure of claim 1, wherein the workspace enclosure is modular.

29. A workspace enclosure for enclosing a workspace adjacent to a cabinet for housing a power system device; the workspace including
a cover member which may be selectively extended from the cabinet to provide an enclosure for the workspace, and
a guide member coupled to the cabinet, the guide members including a track for guiding the selective extension of the cover member.

30. The workspace enclosure of claim 29 further including a platform, upon which the cabinet is mounted.

31. The workspace enclosure of claim 29 wherein the guide member may be foldably stored within the cabinet.

32. The workspace enclosure of claim 31 wherein the guide member extends from the cabinet in a direction generally away from and perpendicular to the cabinet.

33. The workspace enclosure of claim 31 wherein the guide member includes an upper hinge and a lower hinge to allow the guide member to be folded and retracted into the cabinet.

34. The workspace enclosure of claim 33 wherein the upper hinge is in a hydraulic hinge to assist in the selectively extending the guide member in the cabinet.

35. The workspace enclosure of claim 31 further including a link for securing one end of the guide member to another end of the guide member, thereby preventing movement of the ends relative to each other during storage thereof.

36. The workspace enclosure of claim 29 further including a protective barrier for engaging the guide member to form a side of the workspace enclosure.

37. The workspace enclosure of claim 36, wherein the guide member further includes a track for guiding the protective barrier to form the side of the workspace enclosure.

38. The workspace enclosure of claim 37, further including multiple tracks situated within the cabinet engaging a plurality of protective barriers such that the plurality protective barriers may be stored in the cabinet.

39. The workspace enclosure of claim 38, further including a track extending out from the cabinet and engaging the plurality of tracks within the cabinet for extension of each of the protective barriers out from the cabinet.

40. The workspace enclosure of claim 38 wherein the guide member further includes an interior track spanning the entire length of the guide member up to the single track for further securing the protective barriers to the guide member.

41. The workspace enclosure of claim 35 wherein the protective barriers comprise a door.

42. The workspace enclosure of claim 35 wherein the protective barriers include a security mechanism for providing controlled access to the workspace enclosure.

43. The workspace enclosure of claim 35 wherein the protective barriers are housed within the cabinet.

44. The workspace enclosure of claim 29 wherein the cabinet includes an HVAC unit.

45. The workspace enclosure of claim 44 wherein the HVAC unit regulates and controls the temperature of the cabinet through a first ventilation system.

46. The workspace enclosure of claim 45 further including a second ventilation system for regulating and controlling the temperature of the workspace enclosure.

47. The workspace enclosure of claim 46 wherein the first ventilation system and second ventilation system are separately controllable.

48. The workspace enclosure of claim 29, wherein the cover member includes a securing mechanism to maintain the cover member in an extended position.

49. The workspace enclosure of claim 29 further including a cover cabinet for housing the cover member.

50. The workspace enclosure of claim 29 further including a pulley mechanism for the selective extending of the cover member.

51. The workspace enclosure of claim 50 further including a motor for operating the pulley.

52. The workspace enclosure of claim 29, further comprising a plurality of cabinets.

53. The workspace enclosure of claim 52, wherein the cover member may be selectively extended from the plurality of cabinets to provide the enclosure for the workspace.

54. The workspace enclosure of claim 52, further comprising an HVAC unit for regulating and controlling the temperature of the plurality of cabinets through a ventilation system between each of the plurality of cabinets.

55. The workspace enclosure of claim 29, wherein the workspace enclosure is modular.
